(19) United States
(12) Patent Application Publication
(10) Pub. No.: US 2024/0256415 A1
(43) Pub. Date: Aug. 1, 2024

(54) TOOLS FOR PERFORMANCE TESTING AUTONOMOUS VEHICLE PLANNERS

(71) Applicant: Five AI Limited, Cambridge (GB)

(72) Inventors: Alejandro BORDALLO, Cambridge (GB); Bence MAGYAR, Cambridge (GB)

(73) Assignee: Five AI Limited, Cambridge (GB)

(21) Appl. No.: 18/564,483

(22) PCT Filed: May 27, 2022
(86) PCT No.: PCT/EP2022/064458

§ 371 Date: Nov. 27, 2023

(30) Foreign Application Priority Data
May 28, 2021 (GB) 2107642.7

(51) Int. Cl. G06F 11/32; G06F 11/34

(52) U.S. Cl. CPC G06F 11/323; G06F 11/3457

(57) ABSTRACT

A computer implemented method of evaluating the performance of a target planner for an ego robot in a scenario, the method comprising: rendering on a display of a graphical user interface of a computer device, a dynamic visualisation of an ego robot moving along a first path in accordance with a first planned trajectory from the target planner and of a comparison ego robot moving along a second path in accordance with a second planned trajectory from a comparison planner; detecting a juncture point at which the first and second trajectories diverge; rendering the ego robot and the comparison ego robot as a single visual object in motion along a common path shared by the first and second paths prior to the juncture point; and rendering the ego robot and the comparison ego robot as separate visual objects on the display along the respective first and second paths from the juncture point.

### FIELD

The present disclosure relates to tools and techniques for testing the performance of autonomous vehicle planners, and methods, systems and computer programs for implementing the same.

### BACKGROUND

There have been major and rapid developments in the field of autonomous vehicles. An autonomous vehicle is a vehicle that is equipped with sensors and autonomous systems that enable it to operate without a human controlling its behaviour. The term autonomous herein encompass semi-autonomous and fully autonomously behaviour. The sensors enable the vehicle to perceive its physical environment, and may include for example cameras, radar and lidar. Autonomous vehicles are equipped with suitably programmed computers that are capable of processing data received from the sensors and making safe and predictable decisions based on the context that has been perceived by the sensors. There are different facets to testing the behaviour of the sensors and autonomous systems aboard a particular autonomous vehicle, or a type of Autonomous Vehicle (AV). AV testing can be carried out in the real-world or based on simulated driving scenarios. An autonomous vehicle under testing (real or simulated) may be referred to as an Ego Vehicle (EV).

One approach to testing in the industry relies on “shadow mode” operation. Such testing seeks to use human driving as a benchmark for assessing autonomous decisions. An autonomous driving system (ADS) runs in shadow mode on inputs captured from a sensor-equipped but human-driven vehicle. The ADS processes the sensor inputs of the human-driven vehicle, and makes driving decisions as if it were notionally in control of the vehicle. However, those autonomous decisions are not actually implemented, but are simply recorded with the aim of comparing them to the actual driving behaviour of the human. “Shadow miles” are accumulated in this manner typically with the aim of demonstrating that the ADS could have performed as well or better than the human driver in some way, such as safety or effectiveness.

### SUMMARY

Existing shadow mode testing has significant drawbacks. Shadow mode testing may flag some scenario where the available test data indicates that an ADS would have performed differently from the human driver. However, there are two fundamental deficiencies in this approach: firstly, shadow mode operation does not provide a reliable indicator of how the ADS would have actually performed in that scenario had it been in control of the vehicle; secondly, to the extent shadow mode operation can meaningfully demonstrate some discrepancy between human and autonomous behaviour, it provides little insight as to the reasons for those discrepancies.

Existing shadow mode systems can, at best, provide some insight into the instantaneous reasoning of the ADS at a particular planning step in the scenario, but no insight as to how it would actually perform over the duration of the scenario.

On the other hand, for the human driver, the opposite is true. The only insights into the human driver behaviour are the actual, final trajectories the human driver decided to take over the course of some driving scenario; but no structured insights as to the reasons for those decisions, or to the long term planning in the mind of the expert human driver. It is not possible to say with any certainty, for example, whether particular events during the scenario caused the human driver to change their mind about some earlier plan; an experienced human driver to whom driving is “second nature” may even be unable to articulate such matters in qualitative terms.

A technique for providing further insight has been developed by the present Applicants and is discussed in UK patent application No. GB2017253.2 (PWF Ref: 419667 GB), the contents of which are herein incorporated by reference. The concept of a reference planner is introduced to enable a systematic comparison to be carried out between a target planner (a planner under test) and the reference planner. The reference planner provides an objective benchmark for assessing the capability of the target planner. Both planners produce comparable plans, and the reference planner provides a more meaningful benchmark than human behaviour. Another benefit of the technique is the ability to implement the method in simulated scenarios, which makes it far more scalable. A reference planner computes a reference plan, and the target planner (the planner under test) computes an ego plan. The ego plans take the form of instantaneous ego trajectories, wherein each trajectory has a “planning horizon” which determines a duration of the trajectory. At the end of a planning horizon, a new ego trajectory is planned based on the latest available information. The planning horizon may be a short time-period, thereby providing seemingly instantaneous planning of ego trajectories. The reference plan may take the form of an instantaneous reference trajectory, wherein the term “instantaneous” has the same meaning as for instantaneous ego trajectories, as described above. A performance score may be used to compare the instantaneous ego trajectory with the instantaneous reference trajectory.

There are many advantages to the above referenced technique wherein a target planner is compared with the reference planner.

For example, the trajectories of the target planner may be compared with the trajectory of the reference planner for the same scenario and may be judged on performance based metrics. In this way it is possible to ascertain that in a particular set of circumstances the reference planner performed better than the target planner. However in the context of comparing trajectories which have already been implemented, this is achieved with a global score for each ‘run’. For example, one performance metric is whether or not the ‘run’ satisfied Road Rule criteria. It is possible to assess whether or not a trajectory that was implemented failed a road rule, but it is not easy to assess why the road rule was failed or what might have been done differently. In a situation where the target planner fails a road rule, but the reference planner does not, it can be hard to work out why this might be the case, and what modifications may be needed to the target planner.

The inventors have recognised that it is possible to obtain insight into why one planner failed a road rule, while another planner did not fail the road rule, if it could be established where two traces under comparison diverged. The same principle can be used to obtain insight into where to focus analysis for understanding other performance metrics.

An aspect of the present invention provides a computer implemented method of evaluating the performance of a target planner for an ego robot in a scenario, the method comprising:
rendering on a display of a graphical user interface of a computer device a dynamic visualisation of an ego robot moving along a first path in accordance with a first planned trajectory from the target planner and of a comparison ego robot moving along a second path in accordance with a second planned trajectory from a comparison planner;
detecting a juncture point at which the first and second trajectories diverge;
rendering the ego robot and the comparison ego robot as a single visual object in motion along a common path shared by the first and second paths prior to the juncture point; and
rendering the ego robot and the comparison ego robot as separate visual objects on the display along the respective first and second paths from the juncture point.

The method may comprise indicating a juncture point to a user by rendering a visual indicator on the display at the location on the display where the juncture point was determined between the trajectories.

The comparison planner may be a reference planner which is configured to compute a series of ego plans of the comparison trajectory with greater processing resources than those used by the target planner to compute its series of ego plans.

The method may comprise determining that there are a plurality of juncture points between the first trajectory and the second trajectory, determining that at least one of the multiple juncture points is of significance, and using the at least one juncture point of significance to control the rendering of the ego robot and the comparison robot as separate visual objects.

In certain embodiments the method comprises receiving evaluation data for evaluating the performance of the target planner, the evaluation data generated by applying the target planner in the scenario from an initial scenario state to generate the ego trajectory taken by the ego robot in the scenario, the ego trajectory defined by at least one target trajectory parameter; and
receiving comparison data, the comparison data generated by applying the comparison planner in the scenario from the same initial scenario state to generate the comparison ego trajectory representing the trajectory taken by the comparison ego robot in the scenario, the comparison ego trajectory comprising at least one comparison trajectory parameter;
wherein determining the juncture point comprises determining a point at which the comparison trajectory parameter differs from the actual trajectory parameter.

The method may comprise determining a difference between the actual trajectory parameter and the comparison trajectory parameter at the juncture point; and
comparing the determined difference with a threshold value to identify whether the juncture point is of significance.

The trajectory parameter may comprises position data of a path taken by the ego robot, wherein the difference between the actual trajectory parameter and the comparison trajectory parameter is determined as a distance, and wherein the threshold value represents a threshold distance.

The trajectory parameter may represent motion data of the trajectory and be selected from the group comprising:
speed, acceleration, jerk and snap.

The target planner may comprise a first version of software implementing a planning stack under test. The comparison data may be received from a second version of software implementing the planning stack under test.

The target planner may comprise a first planning stack under test of a first origin. The comparison data may be received from a second planning stack under test from a second origin.

The evaluation data may be generated by applying the target planner in a simulated scenario, in order to compute a series of ego plans that respond to changes in the first instance of the scenario, the first series of ego plans being implemented in the first instance of the scenario to cause changes in the first ego state, wherein the ego trajectory is defined by the changes in the first ego state over a duration of the first instance of the simulated scenario.

The comparison data may be generated in the second instance of a simulated scenario by computing a series of reference plans that correspond to changes in the second instance of the simulated scenario, the series of reference plans being implemented in the second instance of the scenario to cause changes in the second ego state, wherein the comparison trajectory is defined by the changes in the second ego state over a duration of the second instance of the simulated scenario.

At least one of the evaluation data and comparison data may comprises trace data from actual ego trajectories implemented by motion of the ego robot in the real world.

Another aspect of the invention provides a computer system for evaluating the performance of a target planner for an ego robot in a scenario, the computer system comprising a graphical user interface comprising a display, computer memory and one or more processor, wherein computer readable instructions are stored in the computer memory which, when executed by the one or more processor, cause the computer system to implement any of the above defined methods.

A further aspect of the invention provides transitory or non-transitory computer readable media on which is stored computer readable instructions which, when executed by one or more processor, implement any of the above defined methods.

The techniques described herein may be used to evaluate a system under test or stack under test (SUT). This evaluation could be carried out by comparing the SUT with a reference planner. The techniques may also be used to compare different versions of a particular stack or system, or to compare stacks or systems from different sources (for example, from different companies).

For a better understanding of the present invention, reference will now be made by way of example to the accompanying drawings.

### BRIEF DESCRIPTION OF FIGURES

For a better understanding of the present invention and to show how the same may be carried into effect, reference will now be made by way of example to the accompanying drawings in which:

FIG. 1 shows a highly schematic block diagram of a runtime stack for an autonomous vehicle.

FIG. 2 shows a highly schematic block diagram of a testing pipeline for an autonomous vehicle's performance during simulation.

FIG. 3 shows a comparison of a first system under test with a second system under test using the juncture point recognition feature of the introspective oracle.

FIG. 4 shows a highly schematic block diagram of the introspective oracle.

FIG. 5 shows a flowchart that illustrates a method for identifying juncture points in the position traces of two agents.

FIG. 6 shows an exemplary graphical user interface configured to provide a visual rendering of agent traces and juncture points to a user.

FIG. 7 shows the same graphical user interface as in FIG. 6, wherein the visual rendering is of a later point in time than in FIG. 6.

FIG. 8 shows the same graphical user interface as in FIG. 6, wherein the visual rendering is of a later point in time than in FIG. 7.

FIG. 9 shows a highly schematic block diagram of a scenario extraction pipeline.

### DETAILED DESCRIPTION

The present disclosure relates to a control of a graphical user interface (GUI) to enable a user to readily identify a so-called ‘juncture point’ between two traces of respective vehicle ‘runs’. The traces of a first agent and a second agent are aligned initially (the second agent is ‘beneath’ the first agent and hidden by it), such that only the first agent is visible on the GUI. A visible timeline includes a juncture marker which indicates the point in the video, and therefore a frame index of data used to identify a juncture point, at which a juncture occurs. The juncture point which has been recognised is used to control the visualisation on the GUI. That is, at the defined juncture point the paths taken by the agents diverge in the visualisation and both agents become visible on their respective paths.

### Example AV Stack

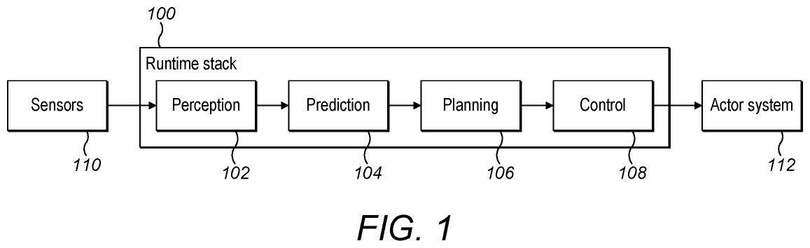

FIG. 1 shows a highly schematic block diagram of a runtime stack 100 for an autonomous vehicle (AV), also referred to herein as an ego vehicle (EV). The run time stack 100 is shown to comprise a perception system 102, a prediction system 104, a planner 106 and a controller 108.

In a real-world context, the perception system 102 would receive sensor inputs from an on-board sensor system 110 of the AV and uses those sensor inputs to detect external agents and measure their physical state, such as their position, velocity, acceleration etc. The on-board sensor system 110 can take different forms but generally comprises a variety of sensors such as image capture devices (cameras/optical sensors), lidar and/or radar unit(s), satellite-positioning sensor(s) (GPS etc.), motion sensor(s) (accelerometers, gyroscopes etc.) etc., which collectively provide rich sensor data from which it is possible to extract detailed information about the surrounding environment and the state of the AV and any external actors (vehicles, pedestrians, cyclists etc.) within that environment. The sensor inputs typically comprise sensor data of multiple sensor modalities such as stereo images from one or more stereo optical sensors, lidar, radar etc.

The perception system 102 comprises multiple perception components which co-operate to interpret the sensor inputs and thereby provide perception outputs to the prediction system 104. External agents may be detected and represented probabilistically in a way that reflects the level of uncertainty in their perception within the perception system 102.

The perception outputs from the perception system 102 are used by the prediction system 104 to predict future behaviour of external actors (agents), such as other vehicles in the vicinity of the AV. Other agents are dynamic obstacles from the perceptive of the EV. The outputs of the prediction system 104 may, for example, take the form of a set of predicted obstacle trajectories.

Predictions computed by the prediction system 104 are provided to the planner 106, which uses the predictions to make autonomous driving decisions to be executed by the AV in a given driving scenario. A scenario is represented as a set of scenario description parameters used by the planner 106. A typical scenario would define a drivable area and would also capture any static obstacles as well as predicted movements of any external agents within the drivable area.

A core function of the planner 106 is the planning of trajectories for the AV (ego trajectories) taking into account any static and/or dynamic obstacles, including any predicted motion of the latter. This may be referred to as trajectory planning. A trajectory is planned in order to carry out a desired goal within a scenario. The goal could for example be to enter a roundabout and leave it at a desired exit; to overtake a vehicle in front; or to stay in a current lane at a target speed (lane following). The goal may, for example, be determined by an autonomous route planner (not shown). In the following examples, a goal is defined by a fixed or moving goal location and the planner 106 plans a trajectory from a current state of the EV (ego state) to the goal location. For example, this could be a fixed goal location associated with a particular junction or roundabout exit, or a moving goal location that remains ahead of a forward vehicle in an overtaking context. A trajectory herein has both spatial and motion components, defining not only a spatial path planned for the ego vehicle, but a planned motion profile along that path.

The planner 106 is required to navigate safely in the presence of any static or dynamic obstacles, such as other vehicles, bicycles, pedestrians, animals etc.

Within the stack 100, the controller 108 implements decisions taken by the planner 106. The controller 108 does so by providing suitable control signals to an on-board actor system 112 of the AV. At any given planning step, having planned an instantaneous ego trajectory, the planner 106 will provide sufficient data of the planned trajectory to the controller 108 to allow it to implement the initial portion of that planned trajectory up to the next planning step. For example, it may be that the planner 106 plans an instantaneous ego trajectory as a sequence of discrete ego states at incrementing future time instants, but that only the first of the planned ego states (or the first few planned ego states) are actually provided to the controller 108 for implementing.

In a physical AV, the actor system 112 comprises motors, actuators or the like that can be controlled to effect movement of the vehicle and other physical changes in the real-world ego state.

Control signals from the controller 108 are typically low-level instructions to the actor system 112 that may be updated frequently. For example, the controller 108 may use inputs such as velocity, acceleration, and jerk to produce control signals that control components of the actor system 112. The control signals could specify, for example, a particular steering wheel angle or a particular change in force to a pedal, thereby causing changes in velocity, acceleration, jerk etc., and/or changes in direction.

### Simulation Testing—Overview

Embodiments herein have useful applications in simulation-based testing. Referring to the stack 100 by way of example, in order to test the performance of all or part of the stack 100 though simulation, the stack is exposed to simulated driving scenarios. The examples below consider testing of the planner 106—in isolation, but also in combination with one or more other sub-systems or components of the stack 100.

In a simulated driving scenario, an ego agent implements decisions taken by the planner 106, based on simulated inputs that are derived from the simulated scenario as it progresses. Typically, the ego agent is required to navigate within a static drivable area (e.g. a particular static road layout) in the presence of one or more simulated obstacles of the kind a real vehicle needs to interact with safely. Dynamic obstacles, such as other vehicles, pedestrians, cyclists, animals etc. may be represented in the simulation as dynamic agents.

The simulated inputs are processed in exactly the same way as corresponding physical inputs would be, ultimately forming the basis of the planner's autonomous decision-making over the course of the simulated scenario. The ego agent is, in turn, caused to carry out those decisions, thereby simulating the behaviours of a physical autonomous vehicle in those circumstances. In simulation, those decisions are ultimately realized as changes in a simulated ego state. There is a two-way interaction between the planner 106 and the simulator, where decisions taken by the planner 106 influence the simulation, and changes in the simulation affect subsequent planning decisions. The results can be logged and analysed in relation to safety and/or other performance criteria.

In the context of the present description, a SUT (Stack Under Test) may be considered as a single black-box unit which generates data for the juncture point recognition function. It may be possible to adjust certain parameters of the SUT, or to adjust simulation and perception fuzzing (PRISM, PEM) parameters, but these are not discussed further herein.

Referring to the stack 100 by way of example, if the full stack (including the entire perception system 102) were to be tested, the simulated inputs would take the form of simulated sensor inputs, provided to the lowest-level components of the perception system 120. The perception system 102 would then interpret the simulated sensor input just as it would real sensor data, in order to provide perception outputs (which are simulated in the sense of being derived through interpretation of simulated sensor data). This may be referred to as “full” simulation, and would typically involve the generation of sufficiently realistic simulated sensor inputs (such as photorealistic image data and/or equally realistic simulated lidar/radar data etc.) that, in turn, can be fed to the perception system 102 and processed in exactly the same way as real sensor data. The resulting outputs of the perception system would, in turn, feed the higher-level prediction and planning system, testing the response of those components to the simulated sensor inputs.

Alternatively, in what may be referred to herein as “headless” simulation, simulated perception outputs are computed directly from the simulation, bypassing some or all of the perception system 102. In a real-world context, equivalent perception outputs would be derived by one or more perception components of the perception system 102 interpreting lower-level sensor inputs from the sensors. In headless simulation, those perception components are not applied—instead, the perception outputs of those perception components are computed directly from ground truth of the simulation, without having to simulate inputs to those perception components. For example, for a bounding box detector, instead of generating simulated sensor data and applying the bounding box detector to the simulated sensor data, simulated bounding box detection outputs would instead be computed directly from the simulation.

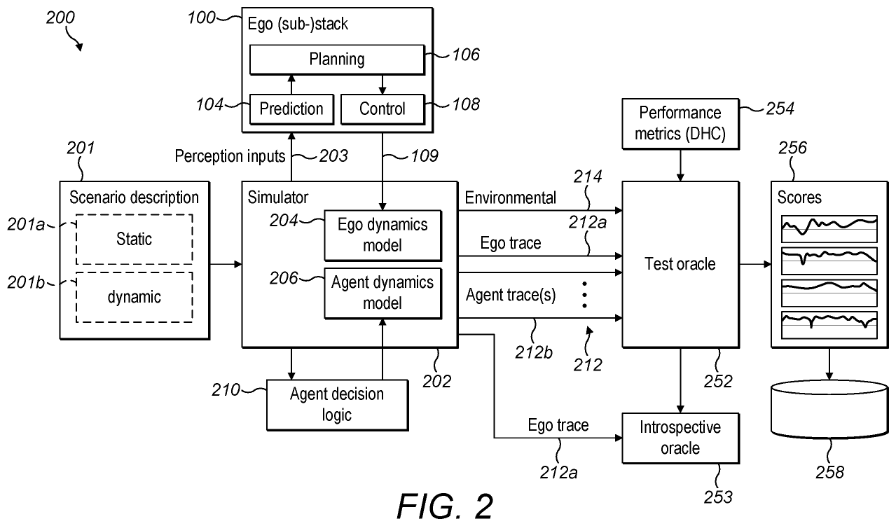

FIG. 2 shows a schematic block diagram of a testing pipeline. The testing pipeline is shown to comprise the simulator 202, a test oracle 252 and an “introspective” oracle 253. The simulator 202 runs simulations for the purpose of testing all or part of an EV runtime stack.

FIG. 2 shows the prediction, planning and control systems 104, 106 and 108 within an AV stack 100 being tested, with simulated perception inputs 203 fed from the simulator 202 to the stack 100. Where the full perception system 102 is implemented in the stack being tested, then the simulated perception inputs 203 would comprise simulated sensor data.

The simulated perception inputs 203 are used as a basis for prediction and, ultimately, decision-making by the planner 108. However, it should be noted that the simulated perception inputs 203 are equivalent to data that would be output by a perception system 102. For this reason, the simulated perception inputs 203 may also be considered as output data. The controller 108, in turn, implements the planner's decisions by outputting control signals 109. In a real-world context, these control signals would drive the physical actor system 112 of AV. The format and content of the control signals generated in testing are the same as they would be in a real-world context. However, within the testing pipeline 200, these control signals 109 instead drive the ego dynamics model 204 to simulate motion of the ego agent within the simulator 202.

To the extent that external agents exhibit autonomous behaviour/decision making within the simulator 202, some form of agent decision logic 210 is implemented to carry out those decisions and drive external agent dynamics within the simulator 202 accordingly. The agent decision logic 210 may be comparable in complexity to the ego stack 100 itself or it may have a more limited decision-making capability. The aim is to provide sufficiently realistic external agent behaviour within the simulator 202 to be able to usefully test the decision-making capabilities of the ego stack 100. In some contexts, this does not require any agent decision making logic 210 at all (open-loop simulation), and in other contexts useful testing can be provided using relatively limited agent logic 210 such as basic adaptive cruise control (ACC). Similar to the ego stack 100, any agent decision logic 210 is driven by outputs from the simulator 202, which in turn are used to derive inputs to the agent dynamics models 206 as a basis for the agent behaviour simulations.

A simulation of a driving scenario is run in accordance with a scenario description 201, having both static and dynamic layers 201a, 201b.

The static layer 201a defines static elements of a scenario, which would typically include a static road layout.

The dynamic layer 201b defines dynamic information about external agents within the scenario, such as other vehicles, pedestrians, bicycles etc. The extent of the dynamic information provided can vary. For example, the dynamic layer 201b may comprise, for each external agent, a spatial path to be followed by the agent together with one or both of motion data and behaviour data associated with the path.

In simple open-loop simulation, an external actor simply follows the spatial path and motion data defined in the dynamic layer that is non-reactive i.e. does not react to the ego agent within the simulation. Such open-loop simulation can be implemented without any agent decision logic 210.

However, in “closed-loop” simulation, the dynamic layer 201b instead defines at least one behaviour to be followed along a static path (such as an ACC behaviour). In this case the agent decision logic 210 implements that behaviour within the simulation in a reactive manner, i.e. reactive to the ego agent and/or other external agent(s). Motion data may still be associated with the static path but in this case is less prescriptive and may for example serve as a target along the path. For example, with an ACC behaviour, target speeds may be set along the path which the agent will seek to match, but the agent decision logic 110 might be permitted to reduce the speed of the external agent below the target at any point along the path in order to maintain a target headway from a forward vehicle.

The output of the simulator 202 for a given simulation includes an ego trace 212a of the ego agent and one or more agent traces 212b of the one or more external agents (traces 212).

A trace is a history of an agent's path within a simulation. A trace may be provided in the form of a set of positions, each position being associated with data [x, y, yaw, Ts] where x and y are the x,y coordinates of the position in Cartesian axes, yaw represents the pose of the agent and Ts is a time stamp representing the time at which the data was logged. Note that the time stamp may be relative to a starting time for the simulation, and may represent a time differential from the starting time, rather than real time.

A trace represents a complete history of an agent's behaviour within a simulation, having both spatial and motion components. For example, a trace may take the form of a previously travelled spatial path having motion data associated with points along the path defining a motion profile. The motion data may be such things as speed, acceleration, jerk (rate of change of acceleration), snap (rate of change of jerk) etc.

Each trace generated by the simulator is supplied to the introspective oracle 253, in some embodiments in association with its test metrics and/or the environmental data. The introspective oracle 253 operates to compare traces of different runs. In particular, it operates to compare a trace of a run simulated in a first stack under test with a run simulated in a second stack under test. The word “run” used herein refers to a particular instance of a simulated scenario or a real-world driving scenario. That is, the term “run” may refer to a particular output of a simulated scenario, or may refer to raw data that has come from a real-world AV.

Runs may be of varying length. For example, runs may be extracted from raw data pertaining to a real-world AV run, in which case a run may theoretically be of any length, even ≥30 minutes. Further, a scenario may be extracted from such raw data, and further runs based on the extracted scenario, of the same theoretically unlimited length as the raw data, may be produced by simulation. Alternatively, a scenario may be human-designed; that is, deliberately constructed to assess a specific AV behaviour. In such cases, a scenario may be as short as ˜50 s. It will be appreciated that the run lengths provided above are by way of example, and should be considered non-limiting.

Additional information is also provided to supplement and provide context to the traces 212. Such additional information is referred to as “environmental” data 214, which can have both static components (such as road layout) and dynamic components (such as weather conditions to the extent they vary over the course of the simulation).

To an extent, the environmental data 214 may be “passthrough” in that it is directly defined by the scenario description 201 and is unaffected by the outcome of the simulation. For example, the environmental data 214 may include a static road layout that comes from the scenario description 201 directly. However, typically the environmental data 214 would include at least some elements derived within the simulator 202. This could, for example, include simulated weather data, where the simulator 202 is free to change weather conditions as the simulation progresses. In that case, the weather data may be time dependent, and that time dependency will be reflected in the environmental data 214.

The present disclosure relates to a juncture point recognition function that is carried out in the introspective oracle. The juncture point recognition function aids the introspective oracle to determine where performance of a planner or planning stack component may be improved. The test oracle is not necessarily required for the method/s described herein. However, it is described to provide context in which the introspective oracle may operate in certain embodiments. For example, in certain embodiments, the test oracle checks if the EV breaks road rules.

The test oracle may be used to automatically select/segment interesting scenarios for further inspection using the introspective oracle, for example in scenarios where a first system under test (SUT 1) fails a given set of rules, since it is known the first SUT1 does not perform well and thus a second system under test SUT 2 may perform better.

Where a test oracle 252 is present, it receives the traces 212 and the environmental data 214, and assesses whether the traces have broken any road rules. This is done by comparing the trace data to a set of “Digital Highway Code” (DHC) or digital driving rules. As mentioned the test oracle may also extract interesting segments of the traces for subsequent analysis by the introspective oracle.

The output of the test oracle (e.g. in this run the EV broke X rules and thus did not behave as well as it could have) can be beneficial as it pre-selects potentially interesting cases, where the introspective oracle will probably find different performance when comparing against a different reference stack.

However ‘run’ data for the introspective oracle can be obtained in a number of ways—the test oracle output is not an essential requirement. Run data may acquired by other means (e.g. a triage engineer may produce or find these during testing the performance of an AV stack in simulated or real scenarios).

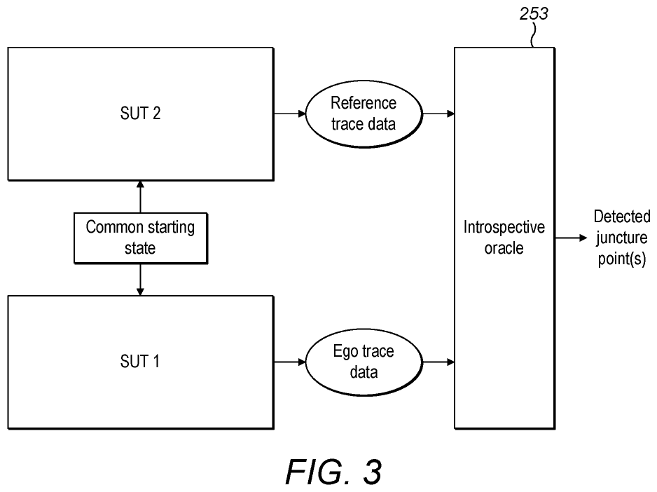

FIG. 3 is an example block diagram showing the comparison of a first system under test SUT 1 with a second system under test SUT 2 using the juncture point recognition feature of the introspective oracle. Each system under test is associated with a simulation. The simulation could be carried out by the same simulator programmed with the respective system under test, or could be carried out by separate simulators. The traces have a common starting state, but are otherwise generated independently by the respective systems under test.

In some embodiments, one of the systems under test may be compared with a reference planner. In that case, the second system under test is a reference planner system. The output is one or more detected juncture points between runs of the systems under comparison.

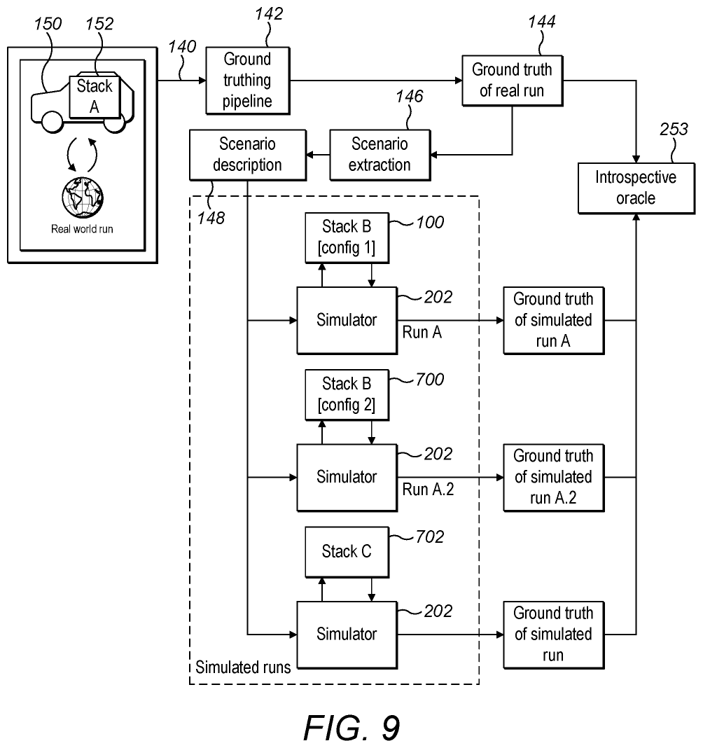

For this application, details of a user run are required. FIG. 9 shows a highly schematic block diagram of a scenario extraction pipeline. Run data 140 of a real-world run is passed to a ground truthing pipeline 142 for the purpose of generating scenario ground truth. The run data 140 could comprise, for example, sensor data and/or perception outputs captured/generated onboard one or more vehicles (which could be autonomous, human driven or a combination thereof), and/or data captured from other sources such as external sensors (CCTV etc.). As shown in FIG. 9, the run data 140 is shown provided from an autonomous vehicle 150 running a planning stack 152, which is labelled stack A. The run data is processed within the ground truthing pipeline 142 in order to generate appropriate ground truth 144 (trace(s) and contextual data) for the real-world run. The ground truthing process could be based on manual annotation of the raw run data 142 or the process could be entirely automated (e.g. using offline perception methods), or a combination of manual and automated ground truthing could be used. For example, 3D binding boxes may be placed around vehicle and/or other agents captured in the run data 140 in order to determine spatial and motion states of their traces. A scenario extraction component 146 receives the scenario ground truth 144 and processes the scenario ground truth to extract a more abstracted scenario description 148 that can be used for the purpose of simulation. The scenario description is supplied to the simulator 202 to enable a simulated run to be executed. In order to do this, the simulator 202 may utilize a stack 100 which is labelled stack B, config 1. The relevance of this is discussed in more detail later. Stack B is the planner stack, which is being used for comparison purposes, to compare its performance against the performance of stack A, which was run in the real run. Stack B could be, for example, a reference stack as described further herein. Note that the run output from the simulator is generated by planner stack B using the ground truth contained in the scenario which was extracted from the real run. This maximizes the ability for planner stack B to perform as well as possible.

The run data from the simulation is supplied to the introspective oracle 253. The ground truth actual run data is also supplied to the introspective oracle.

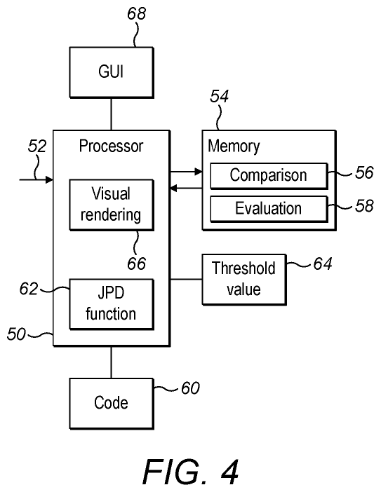

FIG. 4 is a schematic block diagram of the introspective oracle 253. A processor 50 receives data for evaluating the performance of a system under test. The data is received at an input 52. A single input is shown, although it will readily be appreciated that any form of input to the oracle may be implemented. In particular, there may be a different input for evaluation data from a first system under test, and comparison data from a second system under test. The processor 50 stores the received data in a memory 54. In FIG. 4, different portions of the memory are shown holding different types of data. Memory portion 56 holds comparison data and memory portion 58 holds evaluation data. However, this is entirely diagrammatic and it will be appreciated that any manner of storing the incoming data may be implemented. The processor 50 also has access to code memory 60 which stores computer executable instructions, which, when executed by the processor 50, configure the processor 50 to carry out certain functions. The code which is stored in memory 60 could be stored in the same memory as the comparison and evaluation data. It is more likely, however, that the memory for storing the comparison evaluation data will be configured for receiving frame by frame data, whereas the memory 60 for storing code will be internal to the processor.

The processor 50 executes the computer readable instructions from the code memory 60 to execute a juncture point determining function 62. The juncture point determining function 62 accesses the memory 54 to receive comparison and evaluation data as described further herein. The juncture point determining function 62 determines at least one juncture point at which a comparison trace parameter differs from an actual trace parameter of the ego robot under evaluation. It determines a difference between an actual trace parameter and a comparison trace parameter at the determined juncture point. It compares the determined difference with the threshold value to identify whether the juncture point is of significance. In order to determine whether or not the juncture point is of significance, the juncture point determination function 62 accesses a table 64 of threshold values, each threshold value associated with the particular trace parameter.

The introspective oracle 253 can be connected to or incorporate a graphical user interface 68. The processor implements a visual rendering function 66 to control the graphical user interface 68 to present the robot traces and juncture points to a user, as described further herein.

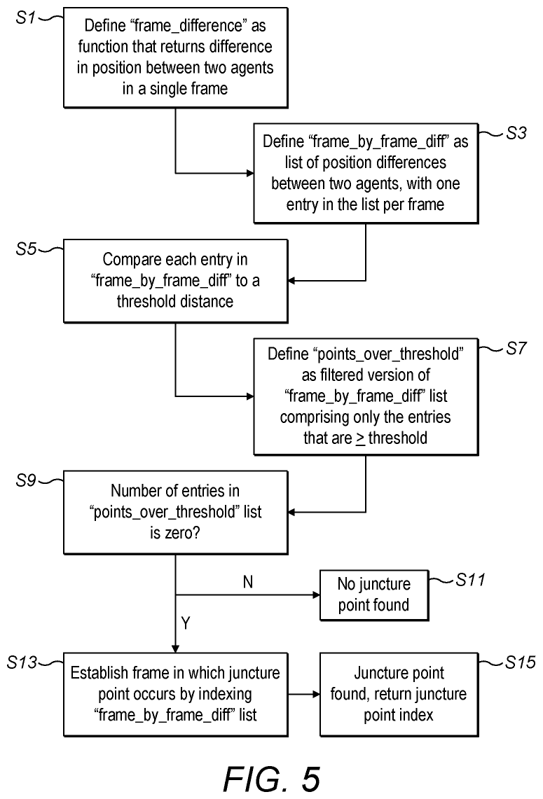

The introspective oracle 253 is configured to determine a juncture point between two traces that it is comparing. This juncture point is identified at the point at which the traces diverge. In one example, described with reference to FIG. 5, the juncture point is defined by position along the respective traces of the agents. Note that in the following description, it is assumed that the traces have been aligned in order to carry out the comparison and identify the juncture point. One way in which the traces may be aligned is to start the scenarios in both cases in the same state and at the same time. Thus, the starting points of the traces are aligned. Another way of aligning the scenarios is to use pattern matching to identify similarities between two traces to enable them to be aligned.

As described more fully below with reference to FIGS. 5 to 8, a juncture point is recognised by identifying where two traces diverge, and then assessing whether or not the divergence is “interesting”. That is, there may be many situations where agent traces diverge but these divergences would not have an impact on any relevant performance metric. It is not useful therefore to identify all points of divergence without assessing whether or not they may be relevant for further investigation. This can be done by assessing whether or not the divergence value at a point where the traces diverge is above a threshold value, based on the divergence metric which is being investigated. In the example of FIG. 5, the divergence relates to position, and therefore the threshold value is a distance value.

There may be more than one point of divergence between two traces (in fact, this is likely), in one or more categories of divergence. In some embodiments, an overall score may be provided which assesses these divergences in a single value. For example, each category of divergence may be weighted to contribute to a total score.

As already mentioned, motion planning data may constitute multiple divergence categories. For example, it is possible to assess where the agent vehicle diverged in terms of speed, acceleration, jerk or snap. This would allow a tester to establish how the runs were different in terms of agent behaviour. For example, in the embodiment described below in one system under test the agent vehicle slowed down in response to a forward vehicle, whereas in another system under test, the agent vehicle sped up and performed an overtake manoeuvre.

In the following description, note that a “frame” may represent an instance at which agent trace data has been recorded. The program may be applied to a set of agent trace data, the set of data including a plurality of frames. The time-separation of frames in a particular set of agent trace data is therefore dependent on a sample rate of the data.

FIG. 5 is a flowchart that illustrates an exemplary method which may be used to identify juncture points in the position traces of two agents. The traces may relate to simulated data, real-world data, or a combination thereof.

In the example of FIG. 5, two agent traces are being analysed, and it is assumed that the timeframes of the two agent traces have been aligned. It will be appreciated that the exemplary function names and list names provided herein may be substituted for any alternative name according to user preference. At a step S1, a user may define a function “frame_difference,” which returns the difference in the positions of the two agent vehicles for a particular frame.

At a step S3, a list entitled “frame_by_frame_diff” may be created. The “frame_by_frame_diff” list may be programmed to store each output of the “frame_difference” function as a separate element. The “frame_by_frame_diff” list comprises a quantity of values, each particular value representing a difference in the positions of the two agents and corresponding to a particular frame in the set of agent trace data.

At a step S5, each element in the “frame_by_frame_diff” list is compared to a predefined threshold value, the threshold value representing an agent separation distance above which a juncture point is considered to have occurred.

At a step S7, a “points_over_threshold” list may be defined, the “points_over_threshold” list being a filtered version of the “frame_by_frame_diff” list, comprising only the elements in the “frame_by_frame_diff” list that exceed the predefined threshold. The “points_over_threshold” list may therefore comprise at least a subset of the elements in the “frame_by_frame_diff” list.

In a step S9, the program may then perform a length command (e.g. “len( )” in PYTHON) to determine the number of elements comprised within the “points_over_threshold” list. If the length command returns zero when applied to the “points_over_threshold” list, the system determines that no elements in the “frame_by_frame_diff” list exceeded the predefined threshold. Therefore, in this case, there are no juncture points in the set of agent trace data; this process is denoted S11. Alternatively, the length command may return a non-zero integer when applied to the “points_over_threshold” list. In this case, the system determines that one or more element in the “frame_by_frame_diff” list exceeds the predefined threshold, the quantity of juncture points identified being the same as the non-zero integer. In a step S13, the program may use an index command on the “frame_by_frame_diff” list to determine in which frame of the agent trace data the juncture point occurred. In a step S15, the program may then return an indication that a juncture point has been identified, and return the index of the frame in which the juncture point occurred. Note that a function entitled, for example, “find_juncture_point_index” may be defined, which, when executed on the trace data for the two agents, executes all of the steps denoted S3 to S15.

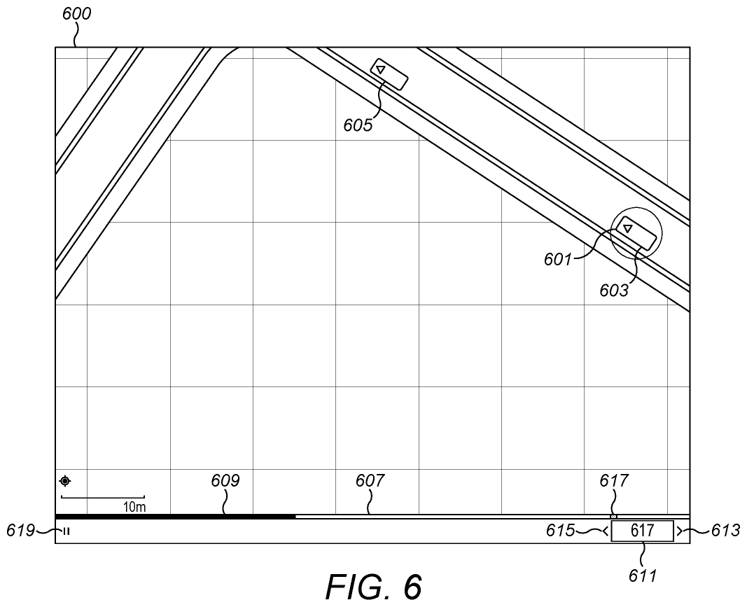

FIG. 6 shows an exemplary graphical user interface (GUI) 600 configured to provide a visual rendering of agent traces and juncture points to a user. This provides an embodiment in which a useful visualisation can be displayed to a user who wishes to quickly and easily compare planning stacks. In this embodiment, there is a method comprising rendering on a display of the graphical user interface a dynamic visualisation of an ego robot moving along a first path in accordance with a first planned trajectory from the target planner and of a comparison ego robot moving along a second path in accordance with a second planned trajectory from a comparison planner. The juncture point at which the first and second trajectories diverge is determined, for example using the techniques described herein. The ego robot and the comparison ego robot are rendered as a single visual object in motion along a common path shared by the first and second paths prior to the juncture point, and as separate visual objects on the display along the respective first and second paths from the juncture point.

The GUI 600 of FIG. 6 provides a visual rendering of a scenario comprising an identified juncture point, the visual rendering being in a video format. The GUI 600 comprises a timeline 607. The timeline 607 may be a selectable feature which, when selected by a user in a particular place on the timeline 607, may cause the associated video to skip to the instance in the scenario corresponding to the selected point on the timeline 607. The timeline 607 also includes a time evolution bar 609 which provides a visual indication of what point in the video the user is viewing. While the video is being played, the time evolution bar 609 may therefore progress along the timeline 607. The GUI 600 further includes a pause button 619, the pause button 619 being configured to stop or start the video upon selection.

The GUI 600 also includes a frame counter 611 which displays a number. The number displayed by the frame counter 611 is the index of a frame in the agent data that is currently being rendered in the video. Whilst the video is being played, the number displayed in the frame counter 611 will change such that the frame number is always consistent with the visual rendering of the traces at that frame. The GUI further includes a forward button 613 and a back button 615, respectively configured to navigate to the next or previous frame in the video.

The GUI 600 of FIG. 6 shows an overlay of the traces of two agents, an ego vehicle 601 and a second agent 603. The video shown in the GUI 600 allows a user to visualise instances in which a juncture point occurs between the two traces. In FIG. 6, the traces of the ego 601 and the second agent 603 are aligned, such that only the ego vehicle 601 is visible on the GUI 600. However, timeline 607 includes a juncture marker 617 which indicates the point in the video, and therefore the frame index of the data (using the frame counter 611), at which a juncture occurs. The juncture point which has been recognised is used to render the visualisation illustrated in FIG. 6. That is, it is the defined juncture point which causes the paths taken by the vehicles to diverge in the visualisation. The GUI 600 further shows an obstacle 605, which may be, for example, a parked car.

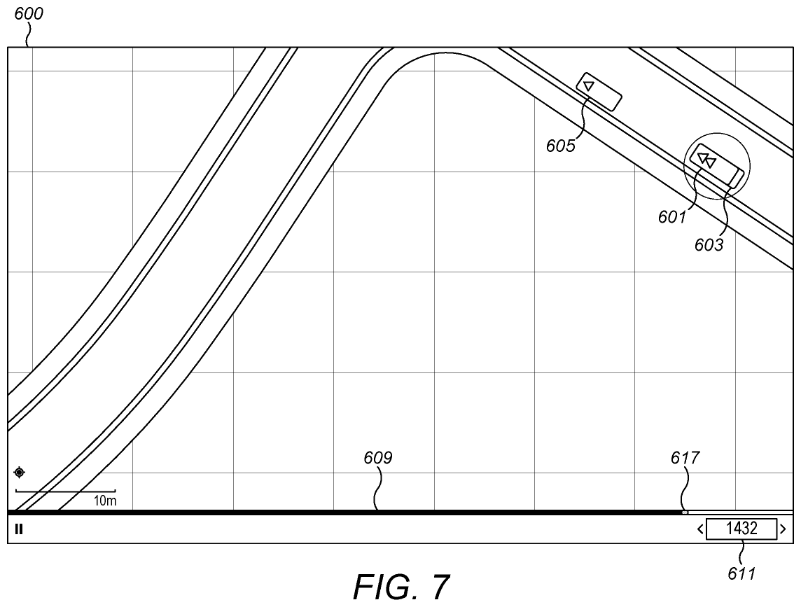

FIG. 7 shows the same GUI 600 as in FIG. 6, the GUI 600 also displaying the same video as in FIG. 6. In FIG. 7, the time evolution bar 609 has progressed further to the right of the timeline 607, and the frame counter 611 accordingly displays a larger number. This indicates that the instance in time shown in FIG. 7 happens later than the instance shown in FIG. 6.

In FIG. 7, the ego vehicle 601 and the second agent 603 have travelled closer to the obstacle 605. However, the traces have begun to diverge, such that the second agent 603 is now partially visible underneath the ego vehicle 601. The time evolution bar 609 is shown to have progressed to the juncture marker on the timeline 607, therefore indicating that the two vehicles have just exceeded a threshold distance at which a juncture point is considered to have occurred.

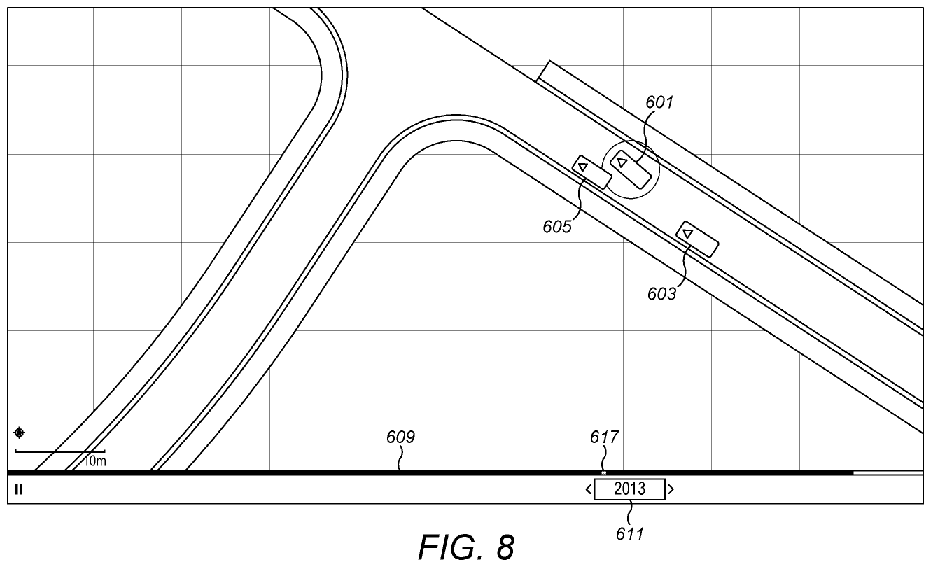

FIG. 8 shows the same GUI 600 as in FIGS. 6 and 7, the GUI 600 also displaying the same video as in FIGS. 6 and 7. In FIG. 8, the time evolution bar 609 has progressed further still to the right of the timeline 607. The frame counter 611 again displays a larger number than in FIG. 7, therefore indicating that the instance displayed in FIG. 8 happens later than the instance shown in FIG. 7. The position of the juncture marker 617 also indicates that the instance shown occurs after the juncture point.

In FIG. 8, the divergence in the traces of the ego vehicle 601 and the second agent 603 is more apparent. The ego vehicle 601 and the second agent 603 are now completely visually distinct; that is, there is no overlap in the graphical representations of the ego 601 and the second agent 603. In the simulation, the ego vehicle trace includes an overtake manoeuvre to overtake the obstacle 605. However, in the second agent trace, there is no such manoeuvre. The second agent 603 is instead remaining stationary behind the obstacle 605.

As discussed herein, certain performance metrics may be provided to the juncture point recognition function of the introspective oracle.

### Performance Metrics

The performance metrics 254 can be based on various factors, such as distance, speed, etc. of an EV run. Alternatively or additionally, conformance to a set of applicable road rules, such as the Highway Code applicable to road users in the United Kingdom is monitored. The terms “Digital Highway Code” (DHC) and “digital driving rules” may be used synonymously herein. The DHC terminology is a convenient shorthand and does not imply any particular driving jurisdiction. The DHC can be made up of any set of road or traffic rules, which may include such rules as staying in a lane, or stopping at a stop sign, for example. A metric may be constructed to measure how well a stack performs in following the set of DHC rules.

Performance metrics 254, focus on how well the vehicle is being driven. By way of example, a vehicle may keep to a lane, but may swerve jerkily between the edges of the lane in a way that is uncomfortable or unsafe for passengers. Use of the performance metrics 254 enables recognition of bad performance such as in the example, even when a set of DHC road rules are followed. The performance metrics 254 may measure, for example, such factors as comfort, safety, actual distance travelled against potential distance travelled, with each factor being assessed in context of the scenario and other agents present. Each metric is numerical and time-dependent, and the value of a given metric at a partial time is referred to as a score against that metric at that time.

Relatively simple metrics include those based on vehicle speed or acceleration, jerk etc., distance to another agent (e.g. distance to closest cyclist, distance to closest oncoming vehicle, distance to curb, distance to centre line etc.). A comfort metric could score the path in terms of acceleration or a first or higher order time derivative of acceleration (jerk, snap etc.). Another form of metric measures progress to a defined goal, such as reaching a particular roundabout exit. A simple progress metric could simply consider time taken to reach a goal. More sophisticated metrics quantify concepts such as “missed opportunities”, e.g. in a roundabout context, the extent to which an ego vehicle is missing opportunities to join a roundabout.

For each metric, an associated “failure threshold” is defined. An ego agent is said to have failed that metric if its score against that metric drops below that threshold.

Not all of the metrics 254 will necessarily apply to a given scenario. For example, a subset of the metrics 254 may be selected that are applicable to a given scenario. An applicable subset of metrics can be selected by the test oracle 252 in dependence on one or both of the environmental data 214 pertaining to the scenario being considered, and the scenario description 201 used to simulate the scenario. For example, certain metric may only be applicable to roundabouts or junctions etc., or to certain weather or lighting conditions.

One or both of the metrics 254 and their associated failure thresholds may be adapted to a given scenario. For example, speed-based metrics and/or their associated failure metrics may be adapted in dependence on an applicable speed limit but also weather/lighting conditions etc.

Juncture Point Recognition may use all of the above metrics as well as other data as its input.

As described herein, one possibility is to compare a first system under test SUT 1 with a second system under test SUT 2, where the second system under test is a reference planner. The reference planner may be able to produce superior trajectories in some circumstances, because it will not necessarily be subject to the same constraints as the target planner. In particular, the first system under test SUT 1 is generally required to operate in real-time, and possibly on a resource-constrained platform (with limited computing and/or memory resources) such as an on-board computer system of an autonomous vehicle. The reference planner need not be subject to the same constraints—it could be granted a greater amount of computing and/or memory resources, and does not necessarily need to operate in real time.

By way of example, reference is made to United Kingdom Patent Application Nos. 2001200.1, 2001202.7 and 2001277.9, and to F. Eiras, M. Hawasly, S. V. Albrecht, and S. Ramamoorthy, “A two-stage optimization approach to safe-by-design planning for autonomous driving,” arXiv preprint arXiv:2002.02215, 2020, each of which is incorporated herein by reference in its entirety. These documents disclose a multi-stage constrained optimization planner, which can robustly plan high-quality trajectories. However, it is not necessarily feasible to implement in real-time using state of the art hardware and solvers (at least, not without compromising performance). Such a planner could be used as a reference planner, to evaluate the performance of a real-time target planner. As will be appreciated, this is just one example of a suitable reference planner.

The examples described herein are to be understood as illustrative examples of embodiments of the invention. Further embodiments and examples are envisaged. Any feature described in relation to any one example or embodiment may be used alone or in combination with other features. In addition, any feature described in relation to any one example or embodiment may also be used in combination with one or more features of any other of the examples or embodiments, or any combination of any other of the examples or embodiments. Furthermore, equivalents and modifications not described herein may also be employed within the scope of the invention, which is defined in the claims.

1. A computer implemented method of evaluating the performance of a target planner for an ego robot in a scenario, the method comprising:
rendering on a display of a graphical user interface of a computer device, a dynamic visualisation of an ego robot moving along a first path in accordance with a first planned trajectory from the target planner and of a comparison ego robot moving along a second path in accordance with a second planned trajectory from a comparison planner;
detecting a juncture point at which the first and second trajectories diverge;
rendering the ego robot and the comparison ego robot as a single visual object in motion along a common path shared by the first and second paths prior to the juncture point; and
rendering the ego robot and the comparison ego robot as separate visual objects on the display along the respective first and second paths from the juncture point.

2. The method according to claim 1, comprising indicating the juncture point to a user by rendering a visual indicator on the display at the location on the display where the juncture point was determined between the trajectories.

3. The method according to claim 1, wherein the comparison planner is a reference planner, which is configured to compute a series of ego plans of the comparison trajectory with greater processing resources than those used by the target planner to compute its series of ego plans.

4. The method according to claim 1, comprising:
determining that there are a plurality of juncture points between the first trajectory and the second trajectory;
determining that at least one of the multiple juncture points is of significance; and
using the at least one juncture point of significance to control the rendering of the ego robot and the comparison robot as separate visual objects.

5. The method according to claim 1, comprising:
receiving evaluation data for evaluating the performance of the target planner, the evaluation data generated by applying the target planner in the scenario from an initial scenario state to generate the ego trajectory taken by the ego robot in the scenario, the ego trajectory defined by at least one target trajectory parameter; and
receiving comparison data, the comparison data generated by applying the comparison planner in the scenario from the same initial scenario state to generate the comparison ego trajectory representing the trajectory taken by the comparison ego robot in the scenario, the comparison ego trajectory comprising at least one comparison trajectory parameter,
wherein determining the juncture point comprises determining a point at which the comparison trajectory parameter differs from the actual trajectory parameter.

6. The method according to claim 5, comprising:
determining a difference between the actual trajectory parameter and the comparison trajectory parameter at the juncture point; and
comparing the determined difference with a threshold value to identify whether the juncture point is of significance.

7. The method according to claim 5, wherein the trajectory parameter comprises position data of a path taken by the ego robot, wherein the difference between the actual trajectory parameter and the comparison trajectory parameter is determined as a distance, and wherein the threshold value represents a threshold distance.

8. The method according to claim 5, wherein the trajectory parameter represents motion data of the trajectory and be selected from the group comprising:
speed, acceleration, jerk and snap.

9. The method according to claim 5, wherein the evaluation data is generated by applying the target planner in a simulated scenario, in order to compute a series of ego plans that respond to changes in the first instance of the scenario, the first series of ego plans being implemented in the first instance of the scenario to cause changes in the first ego state, wherein the ego trajectory is defined by the changes in the first ego state over a duration of the first instance of the simulated scenario.

10. The method according to claim 1, wherein the target planner comprises a first version of software implementing a planning stack under test.

11. The method according to claim 10, when dependent upon claim 5, wherein the comparison data is received from a second version of software implementing the planning stack under test.

12. The method according to claim 1, wherein the target planner comprises a first planning stack under test of a first origin.

13. The method according to claim 12, comprising receiving evaluation data for evaluating the performance of the target planner, the evaluation data generated by applying the target planner in the scenario from an initial scenario state to generate the ego trajectory taken by the ego robot in the scenario, the ego trajectory defined by at least one target trajectory parameter; and
receiving comparison data, the comparison data generated by applying the comparison planner in the scenario from the same initial scenario state to generate the comparison ego trajectory representing the trajectory taken by the comparison ego robot in the scenario, the comparison ego trajectory comprising at least one comparison trajectory parameter,
wherein determining the juncture point comprises determining a point at which the comparison trajectory parameter differs from the actual trajectory parameter,
wherein the comparison data is received from a second planning stack under test from a second origin.

14. The method according to claim 1, wherein the comparison data is generated in the second instance of a simulated scenario by computing a series of reference plans that correspond to changes in the second instance of the simulated scenario, the series of reference plans being implemented in the second instance of the scenario to cause changes in the second ego state, wherein the comparison trajectory is defined by the changes in the second ego state over a duration of the second instance of the simulated scenario.

15. The method according to claim 1, wherein at least one of the evaluation data and comparison data comprises trace data from actual ego trajectories implemented by motion of the ego robot in the real world.

16. A computer system for evaluating the performance of a target planner for an ego robot in a scenario, the computer system comprising a graphical user interface comprising a display, computer memory and one or more processor, wherein computer readable instructions are stored in the computer memory which, when executed by the one or more processor, cause the computer system to implement a method of evaluating the performance of a target planner for an ego robot in a scenario, the method comprising:
rendering on a display of a graphical user interface of a computer device, a dynamic visualisation of an ego robot moving along a first path in accordance with a first planned trajectory from the target planner and of a comparison ego robot moving along a second path in accordance with a second planned trajectory from a comparison planner;
detecting a juncture point at which the first and second trajectories diverge;
rendering the ego robot and the comparison ego robot as a single visual object in motion along a common path shared by the first and second paths prior to the juncture point; and
rendering the ego robot and the comparison ego robot as separate visual objects on the display along the respective first and second paths from the juncture point.

17. A non-transitory computer readable media on which is stored computer readable instructions which, when executed by one or more processor, implement a method of evaluating the performance of a target planner for an ego robot in a scenario, the method comprising:
rendering on a display of a graphical user interface of a computer device, a dynamic visualisation of an ego robot moving along a first path in accordance with a first planned trajectory from the target planner and of a comparison ego robot moving along a second path in accordance with a second planned trajectory from a comparison planner;
detecting a juncture point at which the first and second trajectories diverge;
rendering the ego robot and the comparison ego robot as a single visual object in motion along a common path shared by the first and second paths prior to the juncture point; and
rendering the ego robot and the comparison ego robot as separate visual objects on the display along the respective first and second paths from the juncture point.

18. The computer according to claim 16, wherein the method comprises indicating the juncture point to a user by rendering a visual indicator on the display at the location on the display where the juncture point was determined between the trajectories.

19. The method according to claim 16, wherein the comparison planner is a reference planner, which is configured to compute a series of ego plans of the comparison trajectory with greater processing resources than those used by the target planner to compute its series of ego plans.

20. The computer according to claim 16, wherein the method comprises:
determining that there are a plurality of juncture points between the first trajectory and the second trajectory;
determining that at least one of the multiple juncture points is of significance; and
using the at least one juncture point of significance to control the rendering of the ego robot and the comparison robot as separate visual objects.
